(19) United States
(12) Patent Application Publication
(10) Pub. No.: US 2026/0360455 A1
(43) Pub. Date: Nov. 12, 2026

(54) TEST CIRCUIT AND SEMICONDUCTOR DEVICE CONFIGURED TO PERFORM A TEST

(71) Applicant: SK hynix Inc., Icheon-si Gyeonggi-do (KR)

(72) Inventors: Hong Seok CHOI, Icheon-si Gyeonggi-do (KR); Chang Kwon LEE, Icheon-si Gyeonggi-do (KR); Haeng Seon CHAE, Icheon-si Gyeonggi-do (KR)

(73) Assignee: SK hynix Inc., Icheon-si Gyeonggi-do (KR)

(21) Appl. No.: 19/298,497

(22) Filed: Aug. 13, 2025

(30) Foreign Application Priority Data
May 7, 2025 (KR) 10-2025-0059295

(51) Int. Cl. G11C 29/40; G11C 29/12; G11C 29/26

(52) U.S. Cl. CPC G11C 29/40; G11C 29/1201; G11C 29/26

(57) ABSTRACT

A test circuit includes a transmission data generation circuit configured to generate an error flag based on selected compression data generated from a channel compression test or a pseudo-channel compression test, compare an error counting signal generated by counting the error flags with a target code to generate a fail signal, and drive transmission data based on the fail signal, and a register transmission level circuit configured to generate test output data from the transmission data and transmit the test output data to a direct access region.

### CROSS-REFERENCE TO RELATED APPLICATIONS

The present application claims priority under 35 U.S.C § 119(a) to Korean Application No. 10-2025-0059295, filed in the Korean Intellectual Property Office on May 7, 2025, the entire contents of which application is incorporated herein by reference.

### BACKGROUND

### 1. Technical Field

The present disclosure generally relates to a test circuit and semiconductor device, and more particularly, to a test circuit and semiconductor device configured to perform a test.

### 2. Related Art

Stack memory systems such as a high bandwidth memory (HBM) device are used in a wide range of applications due to their high bandwidth and energy efficiency. Unlike conventional memory systems that use parallel data buses, stack memory system includes a stack memory device including a base die and core dies interconnected by through silicon vias (TSVs). The stack memory device includes a physical interface, such as a physical layer for communication with a processor. The physical layer is designed for high-speed data transmission and efficient communication.

### SUMMARY

The present disclosure provides a test circuit that may include a transmission data generation circuit configured to generate an error flag based on selected compression data generated from a channel compression test or a pseudo-channel compression test, compare an error counting signal generated by counting the error flags with a target code to generate a fail signal, and drive transmission data based on the fail signal; and a register transmission level circuit configured to generate test output data from the transmission data and transmit the test output data to a direct access region.

The present disclosure provides a test circuit that may include a selection circuit configured to select and output one of compression data and pseudo-compression data as selected compression data based on a compression test selection signal; an error flag generation circuit configured to generate an error flag based on the selected compression data; an error flag counter configured to generate an error counting signal based on the error flag and a read strobing signal; a fail signal generation circuit configured to compare the error counting signal and a target code to generate a fail signal; a first drive circuit configured to generate first transmission data from the selected compression data and the fail signal based on a first test mode signal; and a second drive circuit configured to generate second transmission data from the selected compression data and the fail signal based on a second test mode signal.

The present disclosure provides a semiconductor device that may include a plurality of core dies stacked over a base die. In the present disclosure, each of the plurality of core dies may include a plurality of core regions allocated to a plurality of channels, and each of the plurality of channels may include a plurality of pseudo-channels. In the present disclosure, the base die may include a test circuit configured to generate an error flag based on selected compression data generated in a channel compression test or a pseudo-channel compression test, compare an error counting signal generated by counting the error flag with a target code to generate a fail signal, and drive transmission data based on the fail signal.

### BRIEF DESCRIPTION OF THE DRAWINGS

FIG. 1 illustrates a test circuit according to an embodiment of the present disclosure.

FIG. 2 illustrates a core die according to an embodiment of the present disclosure.

FIG. 3 is a table during an operation in which selected compression data is selected in a selection circuit according to an embodiment of the present disclosure.

FIG. 4 is a table during an operation in which a fail signal is generated through comparison between an error counting signal and a target code in a fail signal generation circuit according to an embodiment of the present disclosure.

FIG. 5 is a table during an operation in which first transmission data is driven in a first drive circuit according to an embodiment of the present disclosure.

FIG. 6 is a table during an operation in which second transmission data is driven in a second drive circuit according to an embodiment of the present disclosure.

FIG. 7 illustrates a base die according to an embodiment of the present disclosure.

FIG. 8 illustrates a memory system according to an embodiment of the present disclosure.

### DETAILED DESCRIPTION

In the following description of embodiments, when a parameter is referred to as being “preset” or “predetermined,” it may be intended to mean that a value of the parameter is determined in advance when the parameter is used in a process or an algorithm. The value of the parameter may be set when the process or the algorithm starts or may be set during a period in which the process or the algorithm is executed. For example, a preset number of times means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

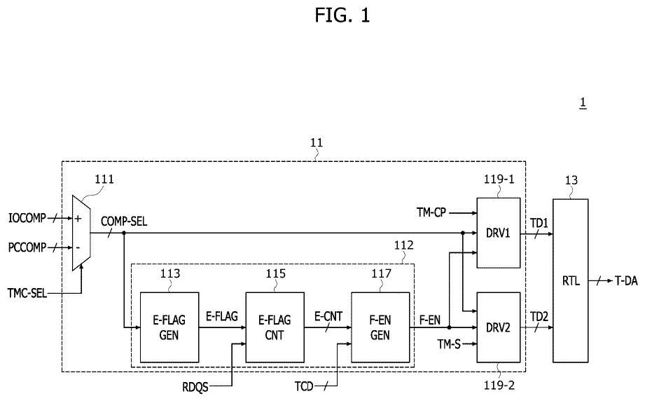

FIG. 1 illustrates a test circuit 1 according to an embodiment of the present disclosure.

As shown in FIG. 1, the test circuit 1 includes a transmission data generation circuit 11 and a register transmission level circuit (RTL) 13. The transmission data generation circuit 11 includes a selection circuit 111, a fail determination circuit 112, a first drive circuit (DRV1) 119-1, and a second drive circuit (DRV2) 119-2.

The selection circuit 111 selects and outputs one of compression data IOCOMP and pseudo-compression data PCCOMP as selected compression data COMP-SEL based on a compression test selection signal TMC-SEL. The selection circuit 111 selects and outputs the compression data IOCOMP as the selected compression data COMP-SEL when the compression test selection signal TMC-SEL is at a first logic level, and selects and outputs the pseudo-compression data PCCOMP as the selected compression data COMP-SEL when the compression test selection signal TMC-SEL is at a second logic level. The compression test selection signal TMC-SEL is set at the first logic level when a channel compression test is performed, and is set at the second logic level when a pseudo-channel compression test is performed. The first logic level may be set to a logic high level and the second logic level may be set to a logic low level, but this is only an example and the present disclosure is not limited thereto.

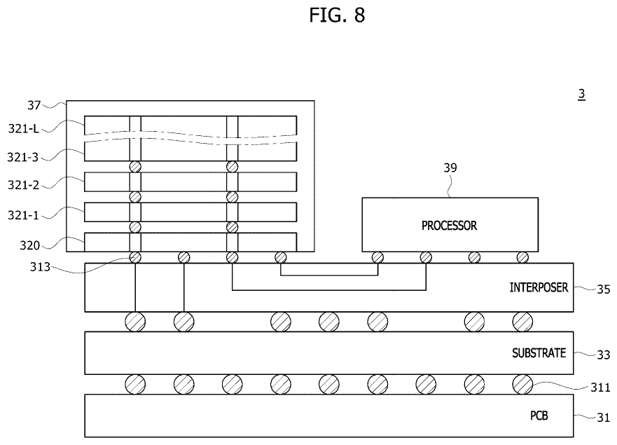

The channel compression test is performed by comparing data output through a plurality of channels among data stored in memory cell arrays for each pseudo channel and burst length according to a read operation to generate compressed data IOCOMP after a write operation of storing data of the same logic level through the plurality of channels is performed on the memory cell arrays (not shown) included in a memory device, for example, a memory device 37 of FIG. 8. For example, a first bit IOCOMP<1> of the compression data may be generated by comparing data output through a first pseudo-channel with a first burst length among data output through first channel to fourth channel. The first bit IOCOMP<1> of the compression data may be set at the first logic level when all data output through the first pseudo-channel with the first burst length among the data output through the first to fourth channels are the same, and may be set at the second logic level when at least one of the data output through the first pseudo-channel with the first burst length among the data output through the first to fourth channels is different from the others. As another example, a second bit IOCOMP<2> of the compression data may be generated by comparing the data output through the first pseudo-channel with a second burst length among the data output through the first to fourth channels. Each channel may include a plurality of pseudo-channels, and when the burst length is set to fourth (4), data with first to fourth burst lengths may be sequentially output to each data pad, but this is only an example and the present disclosure is not limited thereto.

The pseudo-channel compression test may be performed by comparing the data with the plurality of burst lengths output through specific pseudo-channels among the data stored in the memory cell arrays according to a read operation to generate the pseudo-compression data PCCOMP after performing a write operation of storing data of the same logic level through the plurality of channels in the memory cell arrays included in the memory device. For example, a first bit PCCOMP<1> of the pseudo-compression data may be generated by comparing the data with the first to fourth burst lengths output through the first pseudo-channel. In this case, the first bit PCCOMP<1> of the pseudo-compression data may be set at the first logic level when the data with the first to fourth burst lengths output through the first pseudo-channel are all the same, and may be set at the second logic level when at least one of the data with the first to fourth burst lengths output through the first pseudo-channel is different from the others. As another example, the data with the first to fourth burst lengths output through a second pseudo-channel may be compared and output a second bit PCCOMP<2> of the pseudo-compression data.

The fail determination circuit 112 generates a fail signal F-EN as activated when an error flag E-FLAG is activated a preset number of times based on the selected compression data COMP-SEL. The fail determination circuit 112 includes an error flag generation circuit (E-FLAG GEN) 113, an error flag counter (E-FLAG CNT) 115, and a fail signal generation circuit (F-EN GEN) 117.

The error flag generation circuit 113 is electrically connected to the selection circuit 111 and receives the selected compression data COMP-SEL from the selection circuit 111. The error flag generation circuit 113 generates the error flag E-FLAG based on the selected compression data COMP-SEL. The error flag generation circuit 113 generates the error flag E-FLAG activated at the first logic level when a channel compression test is performed to output the compression data IOCOMP as the selected compression data COMP-SEL and the logic level of at least one of all bits included in the selected compression data COMP-SEL is different from the logic levels of the other bits. The error flag generation circuit 113 generates the error flag E-FLAG deactivated at the second logic level when a channel compression test is performed to output the compression data IOCOMP as the selected compression data COMP-SEL and the logic levels of all bits included in the selected compression data COMP-SEL are all the same. The error flag generation circuit 113 generates the error flag E_FLAG activated at the first logic level when a pseudo-channel compression test is performed to output pseudo-compression data PCCOMP as the selected compression data COMP-SEL and the logic level of at least one of all bits included in the selected compression data COMP-SEL is different from the logic levels of the others. The error flag generation circuit 113 generates the error flag E-FLAG deactivated at the second logic level when a pseudo-channel compression test is performed to output the pseudo-compression data PCCOMP as the selected compression data COMP-SEL and all bits included in the selected compression data COMP-SEL are the same.

The error flag counter 115 is electrically connected to the error flag generation circuit 113 and receives the error flag E-FLAG from the error flag generation circuit 113. The error flag counter 115 generates an error counting signal E-CNT based on the error flag E-FLAG and a read strobing signal RDQS. The error flag counter 115 counts the activated error flag E-FALG in synchronization with the read strobing signal RDQS that is activated when a read operation for a channel compression test or a pseudo-channel compression test is performed to generate the error counting signal E-CNT.

The error flag counter 115 generates the error counting signal E-CNT of a binary bit set that is counted and increased by 1 bit each time the error flag E-FLAG is generated, which is activated when at least one of the data stored in the memory cell arrays allocated to all channels is different from the others according to a channel compression test. For example, the error flag counter 115 generates the error counting signal E-CNT<2:0> having a binary bit set of “001” when the error flag E-FLAG is first activated in synchronization with the read strobing signal RDQS by the channel compression test, and generates the error counting signal E-CNT<2:0> having a binary bit set of “010” when the error flag E-FLAG is activated for the second time in synchronization with the read strobing signal RDQS by the channel compression test.

The error flag counter 115 generates the error counting signal E-CNT having a binary bit set that is counted and increased by 1 bit each time the error flag E-FLAG is generated, which is activated when one of the data stored in the memory cell arrays allocated to all pseudo-channels is different from the others according to a pseudo-channel compression test. For example, the error flag counter 115 generates the error counting signal E-CNT<2:0> having a binary bit set of “001” when the error flag E-FLAG is first activated in synchronization with the read strobing signal RDQS by the pseudo-channel compression test, and generates the error counting signal E-CNT<2:0> having a binary bit set of “010” when the error flag E-FLAG is activated for the second time in synchronization with the read strobing signal RDQS by the pseudo-channel compression test.

The fail signal generation circuit 117 is electrically connected to the error flag counter 115 and receives the error counting signal E-CNT from the error flag counter 115. The fail signal generation circuit 117 compares the error counting signal E-CNT and a target code TCD to generate the fail signal F-EN. The fail signal generation circuit 117 generates the fail signal F-EN activated at a first logic level when a binary bit set of the error counting signal E-CNT is the same as the binary bit set of the target code TCD. The fail signal generation circuit 117 generates the fail signal F-EN deactivated at a second logic level when the binary bit set of the error counting signal E-CNT is different from the binary bit set of the target code TCD. The target code TCD may be set to have a binary bit set corresponding to a preset number of times the error flag E-FLAG is activated, which is used to activate the fail signal F-EN in a channel compression test.

The transmission data generation circuit 11 may drive transmission data (e.g., first transmission data TD1 and second transmission data TD2) based on the fail signal F-EN. For example, the first drive circuit 119-1 is electrically connected to the selection circuit 111 and the fail signal generation circuit 117, receives the selected compression data COMP-SEL from the selection circuit 111, and receives the fail signal F-EN from the fail signal generation circuit 117. The first drive circuit 119-1 generates first transmission data TD1 from the selected compression data COMP-SEL and the fail signal F-EN based on a first test mode signal TM-CP. The first test mode signal TM-CP may be set at a first logic level when a channel compression test or a pseudo-channel compression test is performed, and may be set at a second logic level when neither the channel compression test nor the pseudo-channel compression test is performed. The first drive circuit 119-1 generates the fail signal F-EN as the first transmission data TD1 when a channel compression test or a pseudo-channel compression test is performed and the first test mode signal TM-CP set at the first logic level is received. The first drive circuit 119-1 generates the selected compression data COMP-SEL as the first transmission data TD1 when neither the channel compression test nor the pseudo-channel compression test is performed and the first test mode signal TM-CP set at the second logic level is received.

The transmission data generation circuit 11 may drive transmission data (e.g., first transmission data TD1 and second transmission data TD2) based on the fail signal F-EN. For example, the second drive circuit 119-2 is electrically connected to the selection circuit 111 and the fail signal generation circuit 117, receives the selected compression data COMP-SEL from the selection circuit 111, and receives the fail signal F-EN from the fail signal generation circuit 117. The second drive circuit 119-2 generates second transmission data TD2 from the selected compression data COMP-SEL and the fail signal F-EN based on a second test mode signal TM-S. The second test mode signal TM-S may be set at the first logic level when a fixed test is performed, and may be set at the second logic level when the fixed test is not performed. The second drive circuit 119-2 generates the second transmission data TD2 fixed at the first logic level when the fixed test is performed, the second test mode signal TM-S set at the first logic level is received, and the fail signal F-EN is activated. The second drive circuit 119-2 generates the selected compression data COMP-SEL as the second transmission data TD2 when the fixed test is not performed and the second test mode signal TM-S set at the second logic level is received. The fixed test may be performed to set the second transmission data TD2 fixed at the first logic level to be output from the second drive circuit 119-2 when the fail signal F-EN is activated.

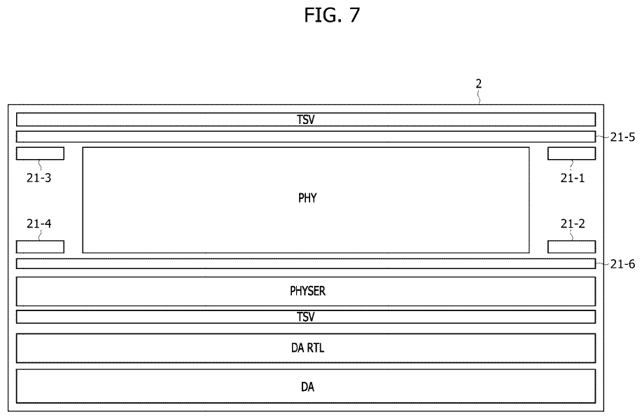

The register transmission level circuit 13 is electrically connected to the transmission data generation circuit 11 and receives the first transmission data TD1 and the second transmission data TD2 from the transmission data generation circuit 11. The register transmission level circuit 13 outputs the first transmission data TD1 and the second transmission data TD2 as test output data T-DA. The test output data T-DA is output through pads of the direct access region, for example, a direct access region DA of FIG. 7.

The test circuit 1 configured as described above does not determine whether a failure occurs for each read operation when a channel compression test or a pseudo-channel compression test is performed, but outputs the fail signal F-EN as activated when an error occurs a preset number of times through multiple read operations, thereby for an embodiment reducing test time. In addition, the test circuit 1 outputs the fail signal F-EN fixed at an activated state when an error occurs first among the multiple read operations in a fixed test, thereby for an embodiment reducing the test time.

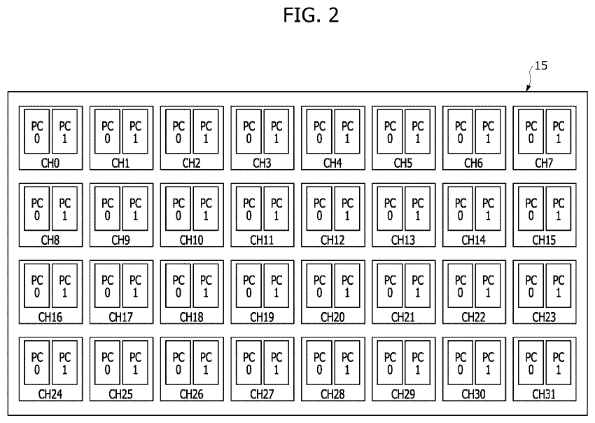

FIG. 2 illustrates a core die 15 according to an embodiment of the present disclosure.

As shown in FIG. 2, the core die 15 includes a plurality of core regions allocated to first channel CH0 to 32^{nd} channel CH31. Each of the core regions includes a memory cell array that is allocated to each of the first channel CH0 to the 32^{nd} channel CH31 and receives and stores data when a channel compression test or a pseudo-channel compression test is performed. Each of the first channel CH0 to the 32^{nd} channel CH31 includes a first pseudo-channel PC0 and a second pseudo-channel PC1. Each of the core regions compares data output through the channels selected from the first channel CH0 to the 32^{nd} channel CH31 for each pseudo-channel and burst length to generate compression data IOCOMP when a channel compression test is performed. Each of the core regions compares the data of multiple burst lengths output through the first pseudo-channel PC0 or the second pseudo-channel PC1 to generate pseudo-compression data PCCOMP when a pseudo-channel compression test is performed. Although it has been explained by way of example that the core regions included in the core die 15 are allocated to the first channel CH0 to the 32^{nd} channel CH31 including the first pseudo-channel PC0 and the second pseudo-channel PC1, it is only an example and the present disclosure is not limited thereto.

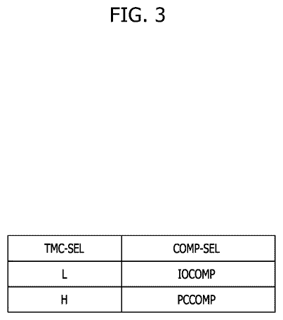

FIG. 3 is a table during an operation in which selected compression data COMP-SEL is selected in a selection circuit 111 according to an embodiment of the present disclosure, for example, as shown in FIG. 1.

Referring to FIG. 3 together with FIG. 1, the selection circuit 111 selects and outputs compression data IOCOMP as the selected compression data COMP-SEL when a compression test selection signal TMC-SEL is at a logic low level “L”, and selects and outputs pseudo-compression data PCCOMP as the selected compression data COMP-SEL when a compression test selection signal TMC-SEL is at a logic high level “H”.

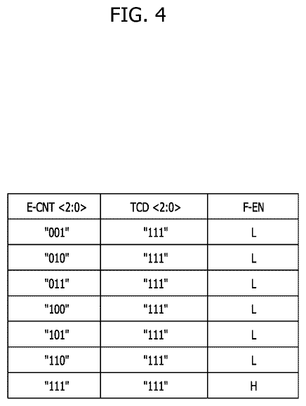

FIG. 4 is a table during an operation in which a fail signal F-EN is generated by comparing an error counting signal E-CNT and a target code TCD in a fail signal generation circuit 117 according to an embodiment of the present disclosure, for example, as shown in FIG. 1.

Referring to a first row in FIG. 4 together with FIG. 1, when an error flag E-FLAG is first activated by a channel compression test or a pseudo-channel compression test and the error counting signal E-CNT<2:0> with a binary bit set of “001” is generated, the fail signal generation circuit 117 generates the fail signal F-EN deactivated at a logic low level “L” because a binary bit set of the target code TCD<2:0> with a binary bit set of “111” and a binary bit set of the error counting signal E-CNT<2:0> are different from each other.

Referring to a second row in FIG. 4 together with FIG. 1, when the error flag E-FLAG is activated for the second time by a channel compression test or a pseudo-channel compression test and the error counting signal E-CNT<2:0> with a binary bit set of “010” is generated, the fail signal generation circuit 117 generates the fail signal F-EN deactivated at a logic low level “L” because the binary bit set of the target code TCD<2:0> with the binary bit set of “111” and the binary bit set of the error counting signal E-CNT<2:0> are different from each other.

Referring to a third row in FIG. 4 together with FIG. 1, when the error flag E-FLAG is activated for the third time by a channel compression test or a pseudo-channel compression test and the error counting signal E-CNT<2:0> with a binary bit set of “011” is generated, the fail signal generation circuit 117 generates the fail signal F-EN deactivated at a logic low level “L” because the binary bit set of the target code TCD<2:0> with the binary bit set of “111” and the binary bit set of the error counting signal E-CNT<2:0> are different from each other.

Referring to a fourth row in FIG. 4 together with FIG. 1, when the error flag E-FLAG is activated for the fourth time by a channel compression test or a pseudo-channel compression test and the error counting signal E-CNT<2:0> with a binary bit set of “100” is generated, the fail signal generation circuit 117 generates the fail signal F-EN deactivated at a logic low level “L” because the binary bit set of the target code TCD<2:0> with the binary bit set of “111” and the binary bit set of the error counting signal E-CNT<2:0> are different from each other.

Referring to a fifth row in FIG. 4 together with FIG. 1, when the error flag E-FLAG is activated for the fifth time by a channel compression test or a pseudo-channel compression test and the error counting signal E-CNT<2:0> with a binary bit set of “101” is generated, the fail signal generation circuit 117 generates the fail signal F-EN deactivated at a logic low level “L” because the binary bit set of the target code TCD<2:0> with the binary bit set of “111” and the binary bit set of the error counting signal E-CNT<2:0> are different from each other.

Referring to a sixth row in FIG. 4 together with FIG. 1, when the error flag E-FLAG is activated for the sixth time by a channel compression test or a pseudo-channel compression test and the error counting signal E-CNT<2:0> with a binary bit set of “110” is generated, the fail signal generation circuit 117 generates the fail signal F-EN deactivated at a logic low level “L” because the binary bit set of the target code TCD<2:0> with the binary bit set of “111” and the binary bit set of the error counting signal E-CNT<2:0> are different from each other.

Referring to a seventh row in FIG. 4 together with FIG. 1, when the error flag E-FLAG is activated for the seventh time by a channel compression test or a pseudo-channel compression test and the error counting signal E-CNT<2:0> with a binary bit set of “111” is generated, the fail signal generation circuit 117 generates the fail signal F-EN activated at a logic high level “H” because the binary bit set of the target code TCD<2:0> with the binary bit set of “111” and the binary bit set of the error counting signal E-CNT<2:0> are the same.

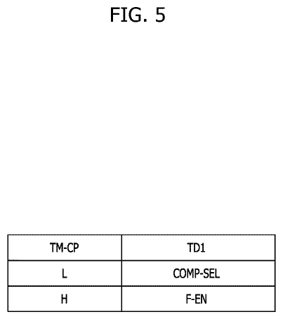

FIG. 5 is a table during an operation in which first transmission data TD1 is driven in a first drive circuit 119-1 according to an embodiment of the present disclosure, for example, as shown in FIG. 1.

As shown in FIG. 5, the first drive circuit 119-1 generates a selected compression data COMP-SEL as the first transmission data TD1 when a channel compression test and a pseudo-channel compression test are not performed and a first test mode signal TM-CP set at a logic low level “L” is received. The first drive circuit 119-1 generates a fail signal F-EN as the first transmission data TD1 when a channel compression test or a pseudo-channel compression test is performed and the first test mode signal TM-CP set at a logic high level “H” is received.

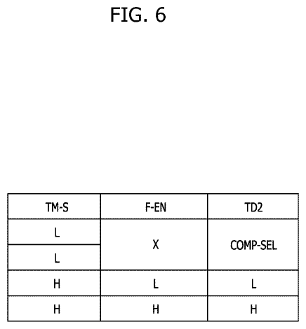

FIG. 6 is a table during an operation in which second transmission data TD2 is driven in a second drive circuit 119-2 according to an embodiment of the present disclosure, for example, as shown in FIG. 1.

As shown in FIG. 6, the second drive circuit 119-2 generates a selected compression data COMP-SEL as the second transmission data TD2 when a fixed test is not performed and a second test mode signal TM-S set at a logic low level “L” is received. The second drive circuit 119-2 generates the second transmission data TD2 fixed at a first logic level when the fixed test is performed, a second test mode signal TM-S set at a logic low level “H” is received, and a fail signal F-EN is activated.

FIG. 7 illustrates a base die 2 according to an embodiment of the present disclosure.

As shown in FIG. 7, the base die 2 includes a physical layer (PHY), a serial-to-parallel conversion circuit (PHYSER), alignment circuits 21-1, 21-2, 21-3, 21-4, 21-5, and 21-6, through silicon via regions (TSV), a direct access region (DA), and a logic circuit region (DA RTL).

The physical layer (PHY) controls transmission of data, commands, and addresses between core dies and a processor, for example, a processor 39 in FIG. 8 through a plurality of channels. The physical layer (PHY) includes data control circuits that control the transmission of data through the plurality of channels and command address control circuits that control the transmission of commands and addresses through the plurality of channels. The physical layer (PHY) is used for high-speed data transmission, maintaining signal integrity, and low-power design in high bandwidth memory (HBM) systems.

The serial-to-parallel conversion circuit (PHYSER) converts serial signals transmitted serially through the physical layer (PHY) into parallel signals, aligns the converted parallel signals through the alignment circuits 21-1, 21-2, 21-3, 21-4, 21-5, and 21-6, and then transmits the converted and aligned parallel signals to the through silicon via regions (TSV). The alignment circuits 21-1, 21-2, 21-3, and 21-4 may be implemented as circuits that align data and the alignment circuits 21-5 and 21-6 may be implemented as circuits that align commands, addresses, and data, but this is only an example and the present disclosure is not limited thereto. The positions and number of the alignment circuits 21-1, 21-2, 21-3, 21-4, 21-5, and 21-6 may be variously modified according to an embodiment. The serial-to-parallel conversion circuit (PHYSER) includes the transmission data generation circuit 11 shown in FIG. 1 to output a fail signal F-EN as activated when an error occurs a preset number of times through a plurality of read operations or output the fail signal F-EN fixed to an activated state when an error occurs for the first time during the plurality of read operations in a fixed test, without determining whether a failure occurs for each read operation when a channel compression test or a pseudo-channel compression test is performed.

The through silicon via regions (TSV) include a plurality of through silicon vias that connect the base die 2 and a plurality of core dies, and transmit the parallel signals transmitted from the serial-to-parallel conversion circuit (PHYSER) to the core dies or output the parallel signals transmitted from the core dies to the serial-to-parallel conversion circuit (PHYSER).

The direct access region (DA) includes pads used to directly access the core dies without going through a memory controller, etc. in a processor, for example, a processor 39 in FIG. 8. Signals used for performing various tests, such as tests based on the IEEE 1500 standard, may be transmitted through the direct access region (DA). In an embodiment, the direct access region (DA) can provide low latency and high bandwidth, and can reduce power consumption.

The logic circuit region (DA RTL) may be implemented as a register transfer level (RTL) circuit and can control or test the operations of core dies, for example, core die 321-1 to core die 321-L in FIG. 8, stacked over the base die 2. The logic circuit region (DA RTL) includes a register transmission level circuit 13 shown in FIG. 1 and outputs first transmission data TD1 and second transmission data TD2 received from the transmission data generation circuit 11 shown in FIG. 1 as test output data T-DA.

FIG. 8 illustrates a memory system 3 according to an embodiment of the present disclosure.

As shown in FIG. 8, the memory system 3 includes a printed circuit board (PCB) 31, a substrate 33, an interposer 35, a memory device 37, and a processor 39.

The printed circuit board 31 connects various electronic components to each other to form electronic circuits. The electronic circuits include the memory system 3. A copper (Cu) layer, a solder mask, a silk screen, and so forth are formed on the printed circuit board 31. Circuit paths that transmit or transfer signals or power are formed in the copper (Cu) layer. In an embodiment, the solder mask prevents or mitigates damage to the circuits and protects a specific region where components are soldered. The silk screen indicates location or information for the electronic components as characters or symbols printed on a surface of the printed circuit board 31.

The substrate 33 is disposed over the printed circuit board 31 with bump pads in between, for example, bump pads 311 and mechanically supports the interposer 35, the memory device 37, and the processor 39. The substrate 33 functions as a physical base for the printed circuit board 31 and is an insulator. The substrate 33 may include materials such as flame retardant 4 (FR4) that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like.

The interposer 35 is disposed over the substrate 33 with bump pads in between and includes wiring that connects electronic components, for example, the memory device 37 and the processor 39, that have form factors or pin arrangements do not match or have different spacing. The interposer 35 converts signals from different interfaces, such as double data rate (DDR), high bandwidth memory (HBM), and peripheral component interconnect express (PCIe).

The memory device 37 is disposed over the interposer 35 with pads in between, for example, micro-bump pads 313. The memory device 37 stores data received from the processor 39 or outputs the stored data to the processor 39 under control of the processor 39. The memory device 37 includes a base die 320 and a plurality of core dies 321-1 to 321-L, where L is an integer greater than 1. The core dies 321-1 to 321-L are stacked over the base die 320 with micro-bump pads in between. The base die 320 and the core dies 321-1 to 321-L are vertically connected to each other using through silicon vias and micro-bump pads. The base die 320 controls efficient data transmission between the processor 39 and the core dies 321-1 to 321-L. The base die 320 receives input/output power voltage (voltage drain drain for IO also referred to as output stage drain power voltage) VDDQ as an operating voltage utilized during operation of internal circuits included in the base die 320. The base die 320 receives the input/output power voltage VDDQ from the printed circuit board 31 through the substrate 33 and the interposer 35. The input/output power voltage VDDQ is a voltage supplied to buffers that transmit data and is distinguished or different from the power supply voltage VDD. The core dies 321-1 to 321-L use a peripheral voltage VPERI as an operating voltage during operation of the internal circuits included in the core dies 321-1 to 321-L. The core dies 321-1 to 321-L generate the peripheral voltage VPERI from the input/output power voltage VDDQ received through the base die 320. The core dies 321-1 to 321-L generate the peripheral voltage VPERI at a lower voltage level than the input/output power voltage VDDQ and use the peripheral voltage VPERI as an operating voltage. Each of the core dies 321-1 to 321-L includes a plurality of channel regions, for example, eight channel regions or forty-six channel regions that operate independently. Each of the plurality of channel regions is allocated with a channel operating independently to receive or transmit data. The number L of core dies 321-1 to 321-L may be four, eight, thirty-two, forty-six, and so forth. For example, when each of the core dies 321-1 to 321-12 has eight channels, the core dies 321-1 to 321-4, the core dies 321-5 to 321-8, and the core dies 321-9 to 321-12 each include thirty-two channel regions, and transmit and receive data with the processor 39 in units of a rank including thirty-two channels.

The base die 320 may include the test circuit 1 shown in FIG. 1. The test circuit 1 included in the base die 320 does not determine whether a failure occurs for each read operation when a channel compression test or a pseudo-channel compression test is performed. Instead, the test circuit 1 outputs a fail signal F-EN as activated when an error occurs a preset number of times through multiple read operations or outputs the fail signal F-EN fixed to an activated state when an error occurs for the first time during the multiple read operations in a fixed test, thereby in an embodiment reducing test time.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

What is claimed is:

1. A test circuit comprising:
a transmission data generation circuit configured to:
generate an error flag based on selected compression data, the selected compression data generated from a channel compression test or a pseudo-channel compression test;
compare an error counting signal with a target code to generate a fail signal, the error counting signal generated by counting the error flag; and
drive transmission data based on the fail signal; and
a register transmission level circuit configured to generate test output data from the transmission data and transmit the test output data to a direct access region.

2. The test circuit of claim 1, wherein the transmission data generation circuit comprises a selection circuit configured to select and output one of compression data and pseudo-compression data as the selected compression data based on a compression test selection signal.

3. The test circuit of claim 2, wherein the selection circuit receives the compression data generated by comparing data output through a plurality of channels from the data stored in memory cell arrays in the channel compression test for each pseudo-channel and burst length.

4. The test circuit of claim 2, wherein the selection circuit receives the pseudo-compression data generated by comparing data of multiple burst lengths output through specific pseudo-channels from the data stored in the memory cell arrays in the pseudo-channel compression test.

5. The test circuit of claim 2, wherein the selection circuit is configured to:
receive the compression test selection signal at a first logic level to select the compression data as the selected compression data in the channel compression test; and
receive the compression test selection signal at a second logic level to select the pseudo-compression data as the selected compression data in the pseudo-channel compression test.

6. The test circuit of claim 1, wherein the transmission data generation circuit comprises a fail determination circuit configured to generate the fail signal as activated when the error flag is activated a preset number of times based on the selected compression data.

7. The test circuit of claim 6, wherein the fail determination circuit comprises an error flag generation circuit configured to generate the error flag based on the selected compression data.

8. The test circuit of claim 7, wherein the error flag generation circuit is configured to:
generate the error flag activated at a first logic level when a logic level of at least one of all bits included in the selected compression data is different from the others; and
generate the error flag deactivated at a second logic level when the logic levels of all bits included in the selected compression data are the same.

9. The test circuit of claim 6, wherein the fail determination circuit comprises an error flag counter configured to generate the error counting signal based on the error flag and a read strobing signal.

10. The test circuit of claim 9, wherein the error flag counter counts the activated error flag in synchronization with the read strobing signal activated when a read operation for the channel compression test or the pseudo-channel compression test is performed to generate the error counting signal.

11. The test circuit of claim 6, wherein the fail determination circuit comprises a fail signal generation circuit configured to compare the error counting signal and the target code to generate the fail signal.

12. The test circuit of claim 11, wherein the fail signal generation circuit is configured to:
generate the fail signal activated at a first logic level when a binary bit set of the error counting signal is the same as a binary bit set of the target code; and
generate the fail signal deactivated at a second logic level when the binary bit set of the error counting signal is different from the binary bit set of the target code.

13. The test circuit of claim 1,
wherein the transmission data comprises first transmission data and second transmission data, and
wherein the transmission data generation circuit comprises a first drive circuit configured to generate the first transmission data from the selected compression data and the fail signal based on a first test mode signal.

14. The test circuit of claim 13, wherein the first drive circuit is configured to:
receive the first test mode signal set at a first logic level to drive the first transmission data based on the fail signal when the channel compression test or the pseudo-channel compression test is performed; and
receive the first test mode signal set at a second logic level to drive the first transmission data based on the selected compression data when the channel compression test and the pseudo-channel compression test are not performed.

15. The test circuit of claim 1,
wherein the transmission data comprises first transmission data and second transmission data, and
wherein the transmission data generation circuit comprises a second drive circuit configured to generate the second transmission data from the selected compression data and the fail signal based on a second test mode signal.

16. The test circuit of claim 15, wherein the second drive circuit is configured to:
generate the second transmission data at a fixed logic level based on the fail signal when a fixed test is performed; and
generate the second transmission data based on the selected compression data when the fixed test is not performed.

17. A test circuit comprising:
a selection circuit configured to select and output one of compression data and pseudo-compression data as selected compression data based on a compression test selection signal;
an error flag generation circuit configured to generate an error flag based on the selected compression data;
an error flag counter configured to generate an error counting signal based on the error flag and a read strobing signal;
a fail signal generation circuit configured to compare the error counting signal and a target code to generate a fail signal;
a first drive circuit configured to generate first transmission data from the selected compression data and the fail signal based on a first test mode signal; and
a second drive circuit configured to generate second transmission data from the selected compression data and the fail signal based on a second test mode signal.

18. The test circuit of claim 17, wherein the selection circuit receives the compression data generated by comparing data output through a plurality of channels from data stored in memory cell arrays in the channel compression test for each pseudo-channel and burst length.

19. The test circuit of claim 17, wherein the selection circuit receives the pseudo-compression data generated by comparing data of multiple burst lengths output through specific pseudo-channels from data stored in memory cell arrays in the pseudo-channel compression test.

20. The test circuit of claim 17, wherein the selection circuit is configured to:
receive the compression test selection signal at a first logic level to select the compression data as the selected compression data in the channel compression test; and
receive the compression test selection signal at a second logic level to select the pseudo-compression data as the selected compression data in the pseudo-channel compression test.

21. The test circuit of claim 17, wherein the error flag generation circuit is configured to:
generate the error flag activated at a first logic level when a logic level of at least one of all bits included in the selected compression data is different from the others; and
generate the error flag deactivated at a second logic level when the logic levels of all bits included in the selected compression data are the same.

22. The test circuit of claim 17, wherein the error flag counter counts the activated error flag in synchronization with the read strobing signal activated when a read operation for the channel compression test or the pseudo-channel compression test is performed to generate the error counting signal.

23. The test circuit of claim 17, wherein the fail signal generation circuit is configured to:
generate the fail signal activated at a first logic level when a binary bit set of the error counting signal is the same as a binary bit set of the target code; and
generate the fail signal deactivated at a second logic level when the binary bit set of the error counting signal is different from the binary bit set of the target code.

24. The test circuit of claim 17, wherein the first drive circuit is configured to:
receive the first test mode signal set at a first logic level to drive the first transmission data based on the fail signal when the channel compression test and the pseudo-channel compression test is performed; and
receive the first test mode signal set at a second logic level to drive the first transmission data based on the selected compression data when the channel compression test and the pseudo-channel compression test are not performed.

25. The test circuit of claim 17, wherein the second drive circuit is configured to:
generate the second transmission data at a fixed logic level based on the fail signal when a fixed test is performed; and
generate the second transmission data based on the selected compression data when the fixed test is not performed.

26. A semiconductor device comprising a plurality of core dies stacked over a base die,
wherein each of the plurality of core dies comprises a plurality of core regions allocated to a plurality of channels, each of the plurality of channels comprising a plurality of pseudo-channels, and
wherein the base die comprises a test circuit configured to:
generate an error flag based on selected compression data, the selected compression data generated in a channel compression test or a pseudo-channel compression test;
compare an error counting signal with a target code to generate a fail signal, the error counting signal generated by counting the error flag; and
drive transmission data based on the fail signal.
